(19) United States
(12) Patent Application Publication
(10) Pub. No.: US 2009/0117270 A1
(43) Pub. Date: May 7, 2009

(54) METHOD FOR TREATING SUBSTRATE AND RECORDING MEDIUM

(75) Inventors: Hideaki Yamasaki, Yamanashi (JP); Kazuhito Nakamura, Aichi (JP); Yumiko Kawano, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Tokyo Electron Limited, Tokyo (JP)

(21) Appl. No.: 12/088,153

(22) PCT Filed: Jul. 25, 2006
(86) PCT No.: PCT/JP2006/314612

§ 371 Date: Mar. 26, 2008

(30) Foreign Application Priority Data
Sep. 26, 2005 (JP) 2005-278367

(51) Int. Cl. C23C 16/02

(52) U.S. Cl. 427/248.1

(57) ABSTRACT

A method for processing a substrate includes a film forming step of supplying a film forming gas into the processing chamber to form a film on the substrate, a cleaning step of supplying a plasma-exited cleaning gas into the processing chamber after the film forming step to clean the inside of the processing chamber, and a coating step of forming a coating within the processing chamber after the cleaning step. The cleaning step includes a high pressure cleaning of regulating the pressure in the processing chamber so that cleaning is mainly performed by molecules formed by recombining radicals in the cleaning gas, and the coating step includes a low temperature film forming step of forming the coating film under the condition that the temperature of a substrate supporting table is set lower than that in the film formation on the substrate during the film formation step.

### FIELD OF THE INVENTION

The present invention relates to a substrate processing method of a film forming apparatus for forming a film on a substrate to be processed, and a storage medium for storing a program for executing the substrate processing method on a computer.

### BACKGROUND OF THE INVENTION

In a film forming apparatus for forming a film on a substrate to be processed such as a chemical vapor deposition (CVD) apparatus, the substrate is mounted in a processing chamber and a specific film formation is performed on the substrate. However, in the film formation process, while a desired thin film is formed on the substrate, a thin film is also attached and deposited to an inner wall of the processing chamber, a substrate supporting table and the like. Upon repetition of the film formation by the film forming apparatus, the thickness of deposits increases, and finally the deposits are peeled off, thereby causing generation of particles.

Therefore, in order to remove the deposits in the processing chamber, a cleaning method using a remote plasma has been proposed (see, e.g., Japanese Patent Laid-open Application No. H10-149989). For example, in the remote plasma cleaning method, a remote plasma generating unit is provided outside the substrate processing chamber for generating fluorine radicals from a cleaning gas, e.g., NF₃ by exciting a plasma. Therefore, the deposits are vaporized by introducing the fluorine radicals into the substrate processing chamber and are discharged out of the substrate processing chamber.

However, since the remote plasma cleaning method mainly uses fluorine radicals in a reactant species for cleaning, in case, for example, a quartz member or the like exist in the substrate processing chamber, the quartz member would be etched. In addition, in case a ceramic member such as AlN, Al₂0₃ or the like is used in the substrate processing chamber, though the ceramic member is etched at a smaller etch rate than quartz member, the ceramic member is etched by a large amount of fluorine radicals introduced into the substrate processing apparatus, thereby forming, e.g., aluminum compound, which remains in the substrate processing chamber. The aluminum compound may be received in a thin film being formed in the film forming process, thereby resulting in a contamination of the film and a poor quality thereof.

### SUMMARY OF THE INVENTION

The present invention provides a novel and useful substrate processing method, and a storage medium for storing a program for executing the substrate processing method on a computer.

In detail, the present invention provides a substrate processing method capable of efficiently and cleanly maintaining a processing chamber of a film forming apparatus and increasing productivity, and a storage medium for storing a program for executing the substrate processing method on a computer.

In accordance with a first aspect of the present invention, there is provided a substrate processing method performed by a film forming apparatus including a substrate supporting table, for supporting a substrate to be processed, and having a heating unit therein, and a processing chamber in which the substrate supporting table is provided, the method including: a film forming step for forming a film on the substrate by supplying a film forming gas into the processing chamber; a cleaning step for cleaning the inside of the processing chamber by supplying a plasma-excited cleaning gas into the processing chamber after the film forming step; and a coating step for forming a coating film in the processing chamber after the cleaning step.

The cleaning step includes a high pressure cleaning where a pressure in the processing chamber is controlled such that the inside of the processing chamber is cleaned mainly by molecules formed by recombining radicals in the plasma-excited cleaning gas, and the coating step includes a low temperature film forming where the coating film is formed under the condition that the temperature of the substrate supporting table is set lower than that in the film formation on the substrate during the film forming step.

In accordance with a second aspect of the present invention, there is provided a storage medium storing a program executing a substrate processing method performed by a film forming apparatus on a computer, the apparatus including a substrate supporting table, for supporting a substrate to be processed, having a heating unit therein, and a processing chamber in which the substrate supporting table is provided, the method includes: a film forming step for forming a film on the substrate by supplying a film forming gas into the processing chamber; a cleaning step for cleaning the inner space of the processing chamber by supplying a plasma-excited cleaning gas into the processing chamber after the film forming step; and a coating step for forming a coating film in the processing chamber.

The cleaning step includes a high pressure cleaning where a pressure in the processing chamber is controlled such that the inside of the processing chamber is cleaned mainly by molecules formed by recombining radicals in the plasma-excited cleaning gas, and the coating step includes a low temperature film forming where the coating film is formed under the condition that the temperature of the substrate supporting table is set lower than that in the film formation on the substrate during the film forming step.

In accordance with the present invention, it is possible to provide a substrate processing method which is capable of efficiently and cleanly maintaining the inside of a processing chamber of a film forming apparatus and increasing productivity, and a storage medium for storing a program for executing the substrate processing method on a computer.

### BRIEF DESCRIPTION OF THE DRAWINGS

FIG. 1 shows a film forming apparatus for performing a substrate processing method in accordance with an embodiment of the present invention.

FIG. 2A illustrates a first example of the substrate processing method in accordance with the embodiment of the present invention.

FIG. 2B presents a second example of the substrate processing method in accordance with the embodiment of the present invention.

FIG. 2C illustrates a third example of the substrate processing method in accordance with the embodiment of the present invention.

FIG. 3 is a graph showing the comparison of etch rates of a W film and a thermal oxidation film.

FIG. 4 is a graph depicting the relationship between a pressure and etching activation energy of a W film.

FIG. 5 is a first graph showing the etch rate ratio of a W film and a thermal oxidation film.

FIG. 6 is a second graph illustrating the etch rate ratio of a W film and a thermal oxidation film.

FIG. 7 is a graph presenting etch rates of a W film in a case of changing a pressure, and a temperature of a substrate supporting table.

FIG. 8 is a graph depicting etch rates of a thermal oxidation film in a case of changing a pressure, and a temperature of the substrate supporting table.

FIGS. 9A and 9B show detection results of contaminants in a film.

FIG. 10 is a graph presenting a vapor pressure of Al fluoride and detection results of Al contaminants in a film;

FIG. 11 is a first graph depicting particle measurement results.

FIG. 12 is a second graph illustrating particle measurement results.

101, 102 processing chamber, 103 exhaust port, 103A pressure control valve, 104 substrate supporting table, 105 supporting table cover, 106 pin installation table, 107 upthrust pins, 108 opening, 109 shower head, 109A diffusion area, 109B gas supply port, 110 gas holes, ill channel, 112 coolant supply source, 113 power supply, 114 gas exhaust unit, 115 driving unit, 116 gate valve, 120, 130, 121, 140, 142, 143 gas line, 130C raw material supply unit, 122, 131 purge line, 120A, 120C, 121A, 121C, 122A, 122C, 130B, 130D, 131A, 131C, 142A, 142C, 143A, 143C valve, 120B, 121B, 130E, 131B mass flow controller, 130A flowmeter, 120D, 121D material gas supply source, 122D, 131D purge gas supply source, 142D cleaning gas supply source, 143D diluent gas supply source

### DETAILED DESCRIPTION OF THE EMBODIMENTS

A substrate processing method in accordance with the present invention is related to a method in which a film forming process, a cleaning process, and a coating process are sequentially performed by using a film forming apparatus.

In the present invention, a pressure in a processing chamber in the film forming apparatus is properly controlled during cleaning, thereby efficiently performing the cleaning process and reducing damage to the processing chamber. In addition, it is possible to maintain the clean interior of the processing chamber by properly keeping a temperature of the coating process. Further, it is possible to increase productivity of the film forming apparatus by improving the cleaning process and processes performed thereafter.

Next, an example of the film forming apparatus capable of performing the substrate processing method will be described.

### First Embodiment

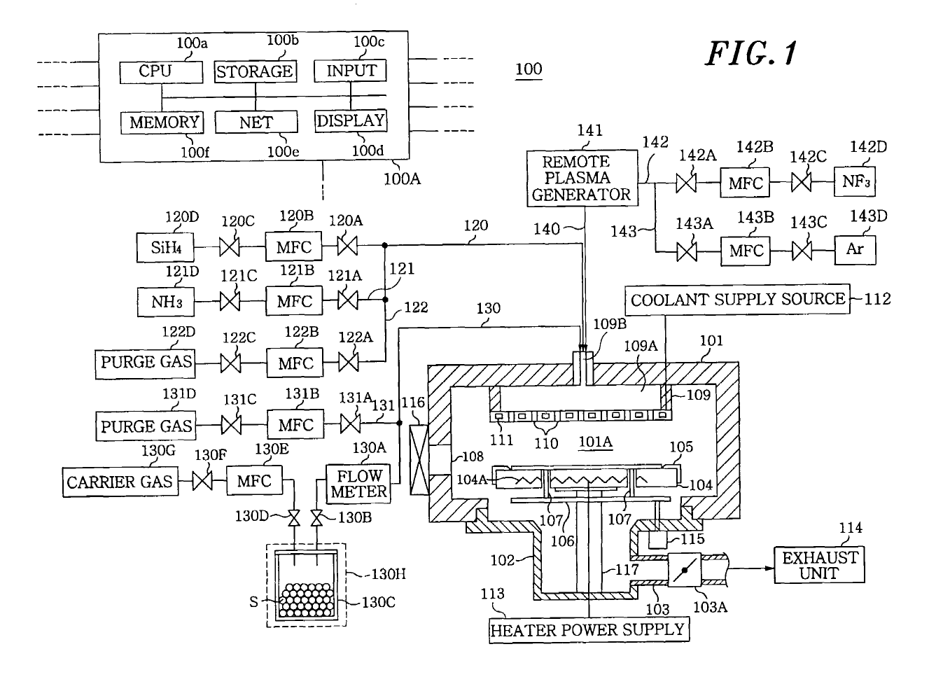

FIG. 1 is a schematic diagram showing a film forming apparatus 100 for performing a substrate processing method in accordance with a first embodiment of the present invention. Referring to FIG. 1, the film forming apparatus 100 includes a processing chamber 101 of a housing shape provided with an opening formed in its bottom, another processing chamber 102 connected with the opening and having a cylindrical part protruded downward, and an inner space 101A defined by the processing chambers 101 and 102. For example, the processing chambers 101 and 102 are formed of aluminum, or a metal material including aluminum such as aluminum alloy.

The inner space 101A can be exhausted through a gas exhaust port 103 provided to the processing chamber 102 to be in a depressurized state by, e.g., a gas exhaust unit 114 such as a vacuum pump or the like. Further, a pressure control valve 103A is installed in the gas exhaust port 103 to control a pressure in the inner space 101A.

Further, a cylindrical support 117 is installed to be upright from a bottom of the processing chamber 102, and a substantially disc-shaped substrate supporting table 104 is installed on the support 117. The substrate supporting table 104 is formed of a ceramic material including, e.g., AlN, Al₂O₃, or the like. A heater 104A connected to a power supply 113 is embedded in the substrate supporting table 104 to heat a substrate W disposed on the substrate supporting table 104.

A substantially annular shaped supporting table cover 105 formed of, e.g., quartz, is installed on the substrate supporting table 104 around the substrate W. The supporting table cover 105 functions to protect the substrate supporting table 104, and adjust a height around the substrate W, thereby aligning the height around the substrate W with a surface of the substrate W and, thus, facilitating uniformity of a film formed on the substrate W.

Further, the substrate supporting table cover 105 has a specific thickness such that a temperature difference is generated between a rear surface (on the side of the substrate supporting table 104) and a front surface (on the side of a shower head 109) of the supporting table cover 105. That is, the supporting table cover 105 functions as a heat buffer member to prevent a high temperature portion thereof from being exposed to a material gas or a cleaning gas.

A structure such as the supporting table cover 105 installed adjacent to the substrate on which a film is formed is preferably formed of a material not including a metal, an organic material, or the like, which may become a contamination source of the film. Further, it preferably has characteristics such as good machining accuracy, heat resistance (about 500° C. to 600° C.), or a small degassing amount upon heating, and the like. For this reason, the supporting table cover 105 is formed of a quartz material that meets the above conditions.

Further, the substrate W disposed on the substrate supporting table 104 is configured to be pushed by upthrust pins 107 installed to penetrate the substrate supporting table 104. The upthrust pins 107 are installed on a pin installation table 106 of a disc shape, and the pin installation table 106 is vertically moved by a driving unit 115 to vertically move the upthrust pin 107.

For example, when the substrate W is unloaded from the processing chamber 101 or when the substrate W loaded from the out side chamber is mounted on the substrate supporting table 104, the upthrust pins 107 are vertically moved.

Further, an opening 108, to which a gate valve 116 is installed, is formed at a sidewall of the processing chamber 101. Therefore, the gate valve 116 is opened and loading/unloading of the substrate W is performed by, e.g., a transfer robot arm.

Further, a shower head 109 is installed at opposite to the substrate supporting table 104 in the processing chamber 101 to supply a material gas into the inner space 101A for performing a film formation on the substrate W. A cleaning gas is also supplied from the shower head 109 to clean the inner space 101A.

The shower head 109 includes a gas supply port 109B for supplying a material gas, a cleaning gas, and the like, from gas lines to be described later, a diffusion area 109A in which the material gas or the cleaning gas is diffused, and gas holes 110 for supplying the material gas or the cleaning gas into the inner space 101A.

Further, the shower head 109 has a channel 111 through which a coolant for cooling the shower head 109 flows. The coolant is supplied to the channel 111 from a coolant supply source 112.

Further, gas lines 120, 130 and 140 are connected to the gas supply port 109B such that a plurality of material gases for the film formation or a cleaning gas plasma-excited in a remote plasma generator (which will be described later) can be supplied to the shower head 109.

First, a material gas supply source 120D is installed at the gas line 120 via valves 120A and 120C and a mass flow controller 120B to supply a material gas such as SiH₄. By opening the valves 120A and 120C and controlling the flow rate of the material gas by the mass flow controller 120B, it is possible to supply the material gas into the inner space 101A.

Further, a gas line 121 is connected to the gas line 120. A material gas supply source 121D is installed at the gas line 121 via valves 121A and 121C and a mass flow controller 121B to supply a material gas such as NH₃ and the like.

By opening the valves 121A and 121C, and controlling the flow rate of the material gas by the mass flow controller 121B, the material gas is supplied into the inner space 101A.

Further, a purge line 122 is connected to the gas line 120. A purge gas supply source 122D is installed at the purge line 122 via valves 122A and 122C and a mass flow controller 122B. By opening the valves 122A and 122C, and controlling a flow rate of a purge gas by the mass flow controller 122B, the purge gas is supplied into the inner space 101A.

Further, a raw material supply unit 130C which maintains a solid raw material S therein is connected to the gas line 130 via a flowmeter 130A and a valve 110B. A heater 130H is attached to the raw material supply unit 130C to heat the solid raw material S and supply a material gas sublimated with a carrier gas which will be described later into the inner space 101A.

Further, a carrier gas supply source 130G is connected to the raw material supply unit 130C via a valve 130D, a mass flow controller 130E, and a valve 130F. By opening the valves 130D and 130F, and controlling a flow rate of a carrier gas by the mass flow controller 130E, the carrier gas is supplied to the raw material supply unit 130C.

Further, a purge line 131 is connected to the gas line 130. A purge gas supply source 131D is installed at the purge line 131 via valves 131A and 131C and a mass flow controller 131B. By opening the valves 131A and 131C, and controlling a flow rate of a purge gas by the mass flow controller 131B, the purge gas is supplied into the inner space 101A.

Further, a remote plasma generator 141 is connected to the gas line 140. The remote plasma generator 141 has a structure for exciting a supplied cleaning gas into plasma by using a high frequency power of, e.g., a frequency of about 400 kHz. Further, the high frequency is not limited to 400 kHz, but plasma excitation may be performed in a range from the high frequency to microwave, e.g., from about 400 kHz to 3 GHz.

A gas line 142 is connected to the remote plasma generator 141. A cleaning gas supply source 142D is installed at the gas line 142 via valves 142A and 142C and a mass flow controller 142B to supply a cleaning gas such as NF₃, and the like. By opening the valves 142A and 142C, controlling the flow rate of the cleaning gas by the mass flow controller 142B, the cleaning gas is supplied to the remote plasma generator 141.

Further, a gas line 143 is connected to the gas line 142. A diluent gas supply source 143D is installed at the gas line 143 via valves 143A and 143C and a mass flow controller 143B to supply a diluent gas such as Ar, or the like. By opening the valves 143A and 143C, and controlling the flow rate of the diluent gas by the mass flow controller 143B, the diluent gas is supplied to the remote plasma generator 141.

The supplied cleaning gas, e.g., NF₃ and the diluent gas are excited into plasma in the remote plasma generator 141, and fluorine radicals are formed as a reactant species that contributes to the cleaning. As a result, the reactant species contributing to the cleaning, which uses mainly the fluorine radicals, is supplied from the remote plasma generator 141 into the inner space 101A through the shower head 109.

Further, in the film forming apparatus 100, operations related to film formation and cleaning, e.g., opening and closing of the valves, control of the flow rates, control of the heater in the substrate supporting table, control of the pressure regulating valve, vertical movement of the upthrust pin, vacuum exhaust and the like, are executed based on a program, which is referred to as a recipe. In this case, these operations are controlled by a controller 100A having a central processing unit (CPU) 100a. Wiring connection thereof is omitted.

The controller 100A includes the CPU 100a, a storage medium 100b in which the program is stored, an input unit 100c such as a keyboard or the like, a display unit 100d, a connection unit 100e to be connected to a network and the like, and a memory 100f.

Hereinafter, a film forming method in accordance with the first embodiment of the present invention using the film forming apparatus 100 will be described.

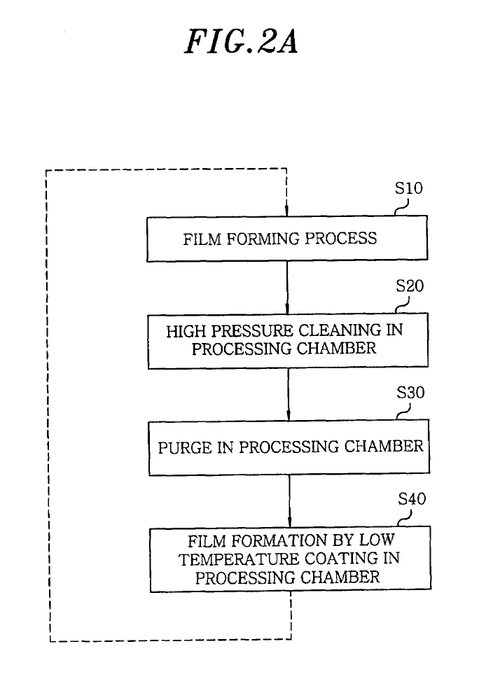

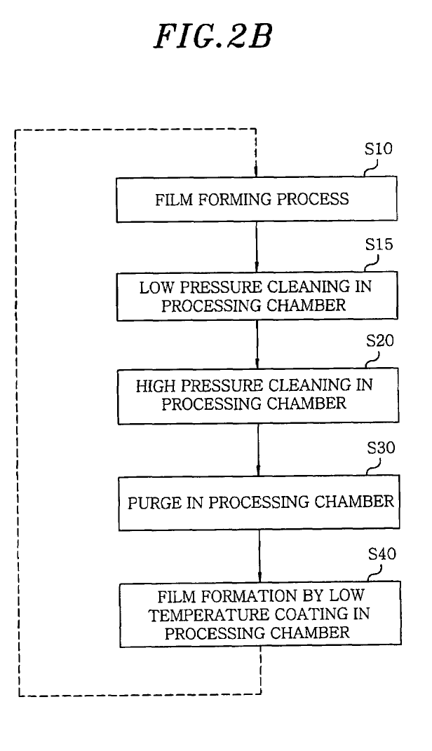

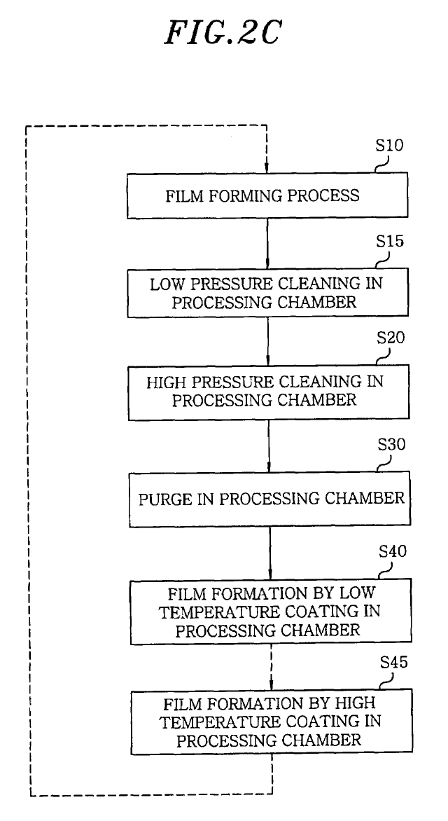

FIG. 2A is a schematic flowchart showing a substrate processing method in accordance with the first embodiment of the present invention. Referring to FIG. 2A, first, in step 10 (presented as S10 in the drawings), a material gas is supplied from the gas line 120 and/or the gas line 130 into the inner space 101A defined by the processing chambers 101 and 102 to perform the film formation (e.g., a W film formation) on the substrate.

Further, the film formation is not limited to be performed on a single substrate, but may be continuously performed on a plurality of substrates.

Next, in step 20, the plasma-excited cleaning gas (e.g., fluorine compound gas such as NF₃, and the like) is supplied into the inner space 101A to clean deposits deposited in the processing chamber 101. In this case, conventionally, etching of the deposits has mainly been performed by using the radicals of the cleaning gas generated in the remote plasma generator 141.

However, in the cleaning of this embodiment, a pressure in the processing chamber 101 (the inner space 101A) is set to a specific level or grater so that the etching of the deposits by molecules in which the radicals are re-bonded is mainly performed in the inner space 101A.

Therefore, it becomes possible to suppress damage to a member in the processing chamber 101 (e.g., quartz forming the supporting table cover 105 and the like), while maintaining an etch rate of a target film to be cleaned (e.g., a W film) at high level. Such a pressure and an etch rate will be described in detail later.

Next, in step 30, the inner space 101A is purged by an inert gas such as Ar, and the like, supplied from the gas line 120 and/or the gas line 130. Although step 30 may be omitted, generation of particles in the processing chamber 101 can be suppressed by the process of step 30.

After the cleaning, in order to suppress diffusion of contaminations such as aluminum fluoride (AlF) and the like, or particle generation into the processing chamber 101, a coating film is formed in the inner space 101A, e.g., on an inner wall of the processing chamber 101 or the substrate supporting table 104. The coating film may be the same material as the film formed on the substrate in step 10.

Conventionally, even though such a coating film is formed, aluminum fluoride was diffused into the processing chamber depending on the film forming conditions of the coating film. As a result, it was difficult to suppress generation of particles or contaminations by using the coating film.

For example, in case of forming the coating film, when the substrate supporting table 104 is heated to a high temperature (e.g., about 500 to 600° C. in case of a CVD method using a metal such as a W film and the like) similar to the conventional film formation, AlF is evaporated and diffused into the inner space 101A (from mainly the substrate supporting table 104) before the coating film is formed.

Therefore, in this embodiment, the temperature of the substrate supporting table 104 in the coating film formation step is lower than that in the general film formation of step 10. Due to this, the surface of the substrate supporting table 104 or the processing chamber 101 is coated, at a condition of low vapor pressure of AlF. As a result, the generation of AlF is suppressed, thereby reducing the generation of particles or contaminations. The correlation between the temperature of the substrate supporting table 104 and generation of AlF in the coating film formation will be described later.

Further, the effect suppressing the generation of AlF by performing the coating film formation at the low temperature may be further increased by combining with the cleaning performed at a high pressure in step 20, in which damage to a member in the processing chamber 101 is reduced. That is, the conventional cleaning mainly using radicals causes not only damage to a member in the processing chamber such as quartz and the like, but also damage to a material forming the supporting table such as AlN, Al₂O₃ or the like, even though the etching amount thereof is small. Therefore, by etching (cleaning) mainly using molecules for suppressing damage to AlN, Al₂O₃ or the like (reaction with F), and by coating film at a low temperature, it is possible to increase the effect of suppressing diffusion of AlF.

After the coating film is formed, the inner space 101A is maintained clean, and the film formation can be performed again by returning to step 10.

As described above, in the substrate processing method in accordance with this embodiment, it is possible to increase an etch rate of deposits to be cleaned, to suppress damage to the processing chamber 101 or the member in the processing chamber 101, and to suppress the generation of AlF and the like. Therefore, it is possible to efficiently maintain the processing chamber 101 of the film forming apparatus 100 in a clean state and to obtain good productivity.

Further, the substrate processing method shown in FIG. 2A may be changed to a method shown in FIG. 2B. In FIG. 2B, like parts are represented by like reference numerals, and redundant description thereof will be omitted.

Referring to FIG. 2B, step 15 is added between step 10 and step 20. In step 15, a pressure in the inner space 101A is set less than that of space 101A of step 20, and cleaning is performed by using the radicals while preventing radicals of the plasma-excited cleaning gas from being extinguished.

This is a method for obtaining a good etching selectivity of an object to be cleaned (for example, a W film) to a member (for example, SiO₂) in the processing chamber 101 in a case where there are sites in the processing chamber 101 such as corners, at which temperatures are not increased due to the structure thereof. Details thereof will be described later.

Further, the substrate processing method shown in FIG. 2B may be changed to a method shown in FIG. 2C. In FIG. 2C, like parts are represented by like reference numerals, and redundant description thereof will be omitted.

Referring to FIG. 2C, step 45 is added after step 40. In step 45, the coating film is formed while a temperature of the substrate supporting table 104 is increased compare with that in step 40 to. By providing this step, it is possible to form a better coating film and improve adhesivity of the coating film.

Next, the effects of the substrate processing method described above will be described based on the test results performed by using the film forming apparatus 100. The present inventors have obtained the following data and graphs by performing experiments with the film forming apparatus 100.

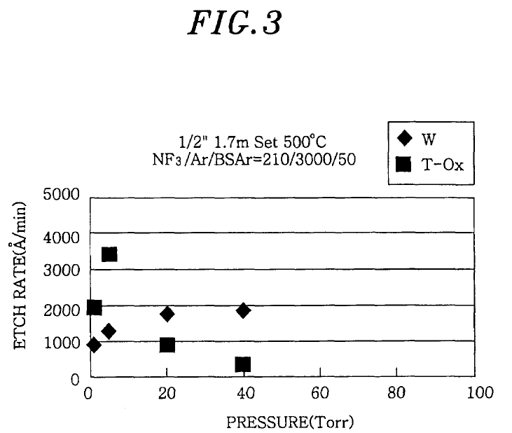

FIG. 3 shows measurement results of etch rates at the inner space 101A (on the substrate supporting table 104) of the film forming apparatus 100 using the cleaning gas excited by the remote plasma generator 141. FIG. 3 presents etch rates of a W film (marked as ♦ W), and etch rates of a thermal oxide film (marked as ▪ T-Ox), in case where the pressure in the inner space 101A was changed. In this case, the flow rate of the cleaning gas (NF₃) was 210 sccm, the flow rate of the diluent gas (Ar) was 3000 sccm, and the temperature of the substrate supporting table 104 was 500° C.

Referring to FIG. 3, as the pressure in the inner space 101A is increased, the etch rate of the thermal oxide film is rapidly decreased. Meanwhile, the etch rate of the W film is gradually increased as the pressure in the inner space 101A is increased.

This is because the F radicals generated by plasma-excited NF₃ are extinguished as the pressure in the inner space 101A is increased, and fluorine is recombined to generate F molecules (F₂) so that etching is mainly performed by the F molecules. Therefore, it is considered that, in particular, the etch rate of the thermal oxide film is rapidly decreased.

In this case, by considering correlation between the etching amount of the thermal oxide film and the etching amount of a quartz material (SiO₂) forming the supporting table cover 105, a damage amount (etching amount) of the quartz material can be suppressed by increasing the pressure in the inner space 101A. Further, it is considered that a damage amount of AlN or Al₂O₃ forming the substrate supporting table 104 can also be reduced.

Meanwhile, the etch rate of the W film is increased as the pressure of the inner space 101A increases.

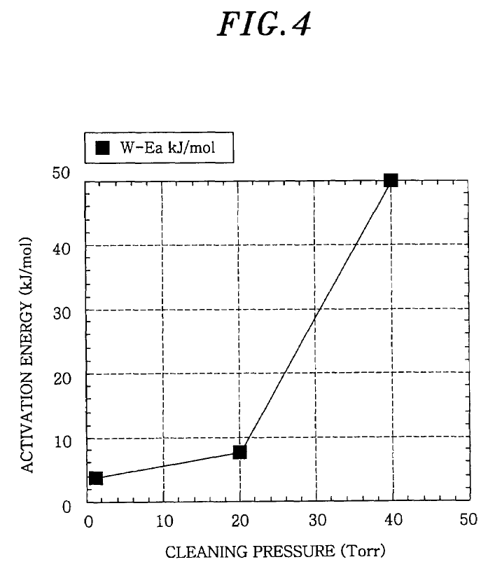

In this case, FIG. 4 shows the relationship between the pressure in the inner space 101A and activation energy in the W film etching. Referring to FIG. 4, it is found that the activation energy is rapidly increased, particularly in a region where the pressure in the inner space 101A is 20 Torr (2666 Pa) or more. That is, it can be seen that the pressure in the inner pressure 101A is preferably about 20 Torr (2666 Pa) or more. In this case, it is possible to suppress damage to the member (quartz and the like) in the processing chamber 101, while the etch rate of the deposits (W film) accumulated in the processing chamber 101 is maintained at a high level.

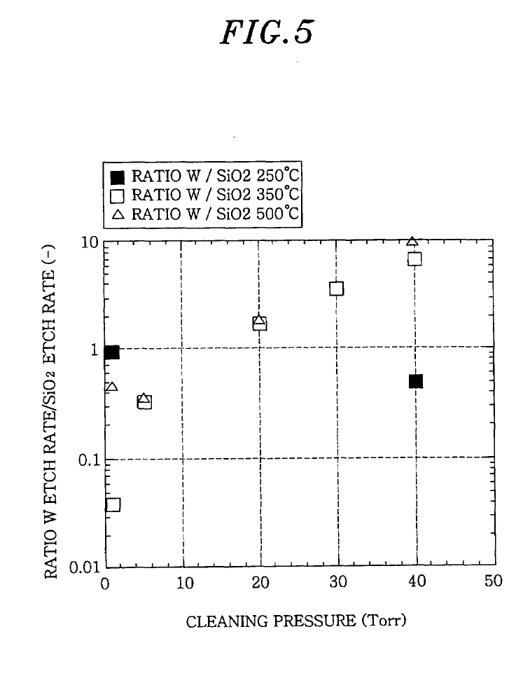

Further, FIG. 5 shows the relationship between the pressure of the inner space 101A and the etch rate ratio of the thermal oxide film and the W film when the temperature of the substrate supporting table 104 was varied (250° C., 350° C. and 500° C.) in the experiment. In this case, the ratio of the etch rates is a ratio of the etch rate of the W film to the etch rate of the thermal oxide film, (the etch rate of the W film)/(the etch rate of the thermal oxide film), (hereinafter, referred to as “etch rate ratio”). In FIG. 5, ▪ represents a result obtained from a case where the temperature of the substrate supporting table 104 was 250° C., □ represents a result obtained from a case where the temperature of the substrate supporting table 104 was 350° C., and ⋄ represents a result obtained from a case where the temperature of the substrate supporting table 104 was set to be 500° C.

Referring to FIG. 5, it is found that when the temperature of the substrate supporting table 104 is 350° C. or 500° C., the etch rate ratio is increased as the pressure of the inner space 101A increases, so that increasing etching efficiency of the target film to be cleaned can be increased while suppressing damage to member in the processing chamber 101.

Meanwhile, when the temperature of the substrate supporting table 104 is 250° C., on the contrary, the etch rate ratio tends to be slightly reduced as the pressure of the inner space 101A is increased. Accordingly, when high pressure cleaning is performed while the pressure of the inner space 101A is about 20 Torr or more, it is preferable that the temperature of the substrate supporting table 104 is about 350° C. or more. That is, in step 20 shown in FIG. 2A, it is preferable that the pressure in the inner space 101A is about 20 Torr (2666 Pa) or more. In this case, it is preferable that the temperature of the substrate supporting table 104 is about 350° C. or more.

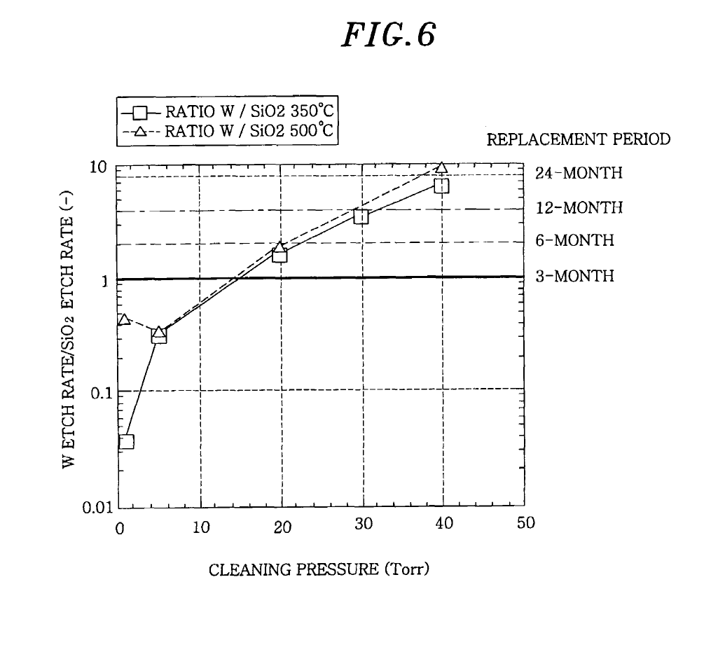

FIG. 6 is a graph showing a replacement cycle of member installed in the inner space 101 (e.g., the supporting table cover 105) in the case of FIG. 5. In FIG. 6, like parts are represented by like reference numerals, and redundant description thereof will be omitted. Further, the case in which the temperature of the substrate supporting table 104 is 250° C. is omitted in FIG. 6.

As described above, since a function of the supporting table cover 105 is determined by its thickness, it needs to be replaced when the thickness of thereof is decreased by about 10%. Therefore, the replacement cycle of the substrate supporting table 104 calculated from the etch rate thereof is presented in FIG. 6, in consideration that the substrate supporting table 104 is used to process a thousand of substrates per month.

Referring to FIG. 6, when the temperatures of the substrate supporting table 104 are 350° C. and 500° C., similar results are obtained. When the pressure of the inner space 101A is 15 Torr (2000 Pa) or more, the replacement period is 3-month or more, and when the pressure is 30 Torr (4000 Pa) or more, the replacement period is about 12-month or more. Therefore, by performing the cleaning under the increased pressure in the inner space 101A, it is possible to reduce damage to the member in the inner space 101A and to prolong the replacement cycle of the member, thereby performing the substrate processing in a high productivity.

Meanwhile, as shown in FIG. 5, when the temperature of the substrate supporting table 104 is 250° C., on the contrary, the etch rate ratio tends to be reduced as the pressure in the inner space 101A increases. The etch rate ratio is rather higher at a lower pressure.

Accordingly, in case where the inner space 101A includes a place where a temperature is difficult to increase, or a place whose temperature is low due to irregularity of the inner space 101A (hereinafter, referred to as “low temperature site”) , the pressure of the inner space 101A is preferably set to be low in order to etch deposits on the low temperature site. In this case, the temperature of the substrate supporting table 104 is preferably set to be low in order to prevent damage to the member.

That is, when the processing chamber 101 including the low temperature site is cleaned, it is preferable to clean the low temperature site by providing a step in which the pressure in inner space 101A is set lower than that of step 20 as in step 15 of the substrate processing method shown in FIG. 2B, and the temperature of the substrate supporting table 104 is set lower than that of step 20.

Further, based on the results shown in FIG. 5, pressure in the inner space 101A is preferably set to be about 10 Torr (1330 Pa) or less, and more preferably, about 5 Torr (665 Pa) or less, and the temperature of the substrate supporting table 104 is preferably set to be about 300° C. or less, in step 15.

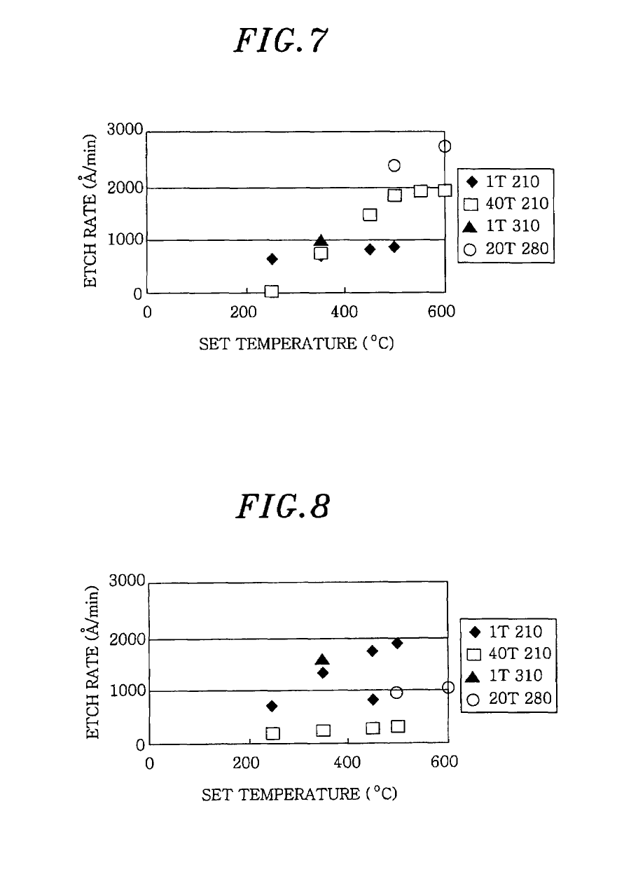

Further, FIGS. 7 and 8 present the etch rates of the W film and the thermal oxide film, respectively, when the pressure of the inner space 101A and the temperature of the substrate supporting table 104 are changed. In each graph, the horizontal axis presents the temperature of the substrate supporting table 104, and the vertical axis presents the etch rate.

Further, in FIGS. 7 and 8, ♦ represents a case where the pressure of the inner space 101A is 1 Torr (133 Pa) and a flow rate of NF₃ is 210 sccm (marked as “♦ 1T 210”) , □ represents a case where the pressure of the inner space 101A is 40 Torr (5332 Pa) and the flow rate of NF₃ is 210 sccm (marked as “□ 40T 210”), ▴ represents a case where the pressure of the inner space 101A is 1 Torr and the flow rate of NF₃ is 310 sccm (marked as “▴ 1T 310”), and ◯ represents a case where the pressure of the inner space 101A is 20 Torr (2666 Pa) and the flow rate of NF₃ is 280 sccm (marked as “◯ 20T 280”).

First, referring to FIG. 7, when the W film is etched, it is found that the etch rate is increased when the pressure of the inner space 101A is high (20 Pa or more) as the temperature of the substrate supporting table 104 increases. Meanwhile, when the temperature in the inner space 101A is low (1 Torr or less), variation of the etch rate depending on the temperature is reduced. Further, when the substrate supporting table 104 is at a low temperature (250° C. or less) , the etch rate is remarkably decreased in the high pressure (20 Pa or more) , so that the etch rate at the lower pressure (1 Torr or less) becomes grater than that at the higher pressure.

Further, referring to FIG. 8, when the thermal oxide film is etched, generally, the etch rate at the lower pressure is greater than that at the higher pressure. However, in cases where the pressure is low (1 Torr or less), the etch rate is rapidly decreased as the temperature is decreased. Therefore, as described with reference to FIG. 5, when the temperature of the substrate supporting table 104 is 250° C., the etch rate ratio at the lower pressure (1 Torr or less) becomes greater than that at the higher pressure, in opposition to the case when the temperature of the substrate supporting table 104 is higher.

In view of the above, it is preferable to increase the temperature of the substrate supporting table 104 (e.g., about 350° C. or more as described above) and increase the pressure in the inner space 101A (e.g., to about 20 Torr or more as described above, more preferably, about 30 Torr or more) in order to increase the etch rate ratio. However, when the inner space 101A has a low temperature site (e.g., 250° C. or less) , it is preferable that the pressure in the inner space 101A is set to be low (about 1 Torr or less). In this case, in order to reduce damage to the substrate supporting table 104 or the supporting table cover 105, the temperature of the substrate supporting table 104 is preferably set to be about 250° C. or less. The low temperature and low pressure cleaning corresponds to the process of step 15 shown in FIG. 2B.

Next, contamination suppression effect of the coating process corresponding to step 40 in FIGS. 2A to 2C will be described.

As described above, after the cleaning, it is possible to prevent diffusion of particles or contaminations by coating a film on inner walls of the processing chambers 101 and 102, the substrate supporting table 104, the supporting table cover 105, the shower head 109 (surfaces thereof facing the inner space 101A) and the like, for example, by suppressing diffusion of AlF.

However, conventionally, even though the film is coated, when a gas including F is used as the cleaning gas, F reacts with the processing chamber or Al in the processing chamber to generate AlF. Diffusion of AlF causes generation of particles or contaminations.

Therefore, in this embodiment, the coating film formation is performed by suppressing the temperature of the substrate supporting table 104 to be lower than that in the general film formation on a substrate, and suppressing diffusion of AlF, and then, the temperature of the substrate supporting table 104 is increased to a temperature required for the general film formation.

For example, when a metal film or a metal nitride film (Si may be added thereto) is formed through a CVD method (MOCVD method), the temperature of the substrate supporting table 104 (substrate to be processed) is preferably set to about 500 to 600° C. or higher. For instance, a WN film, a WSi film or a SiN film is formed by using W(CO)₆, SiH₄, and NH₃, and a TaSiN film is formed by using Ta(Nt-Am) (NMe₂)₃, NH₃, and SiH₄.

Conventionally, when the film is coated, it has been performed through the same method as the general film formation on the substrate, without changing conditions. For this reason, aluminum fluoride formed during the cleaning is sublimated and diffused as the temperature of the substrate supporting table 104 increases. Accordingly, the diffused aluminum fluoride causes contaminations during the film formation, or is solidified in the processing chamber to cause particles.

Therefore, in the embodiment of the present invention, e.g., in step 40 shown in FIGS. 2A to 2C, the temperature of the substrate supporting table 104 is set to be lower than that in step 10 and then the coating film formation is performed so that the film is coated at a low temperature before diffusion of AlF, thereby suppressing generation of contaminations or particles.

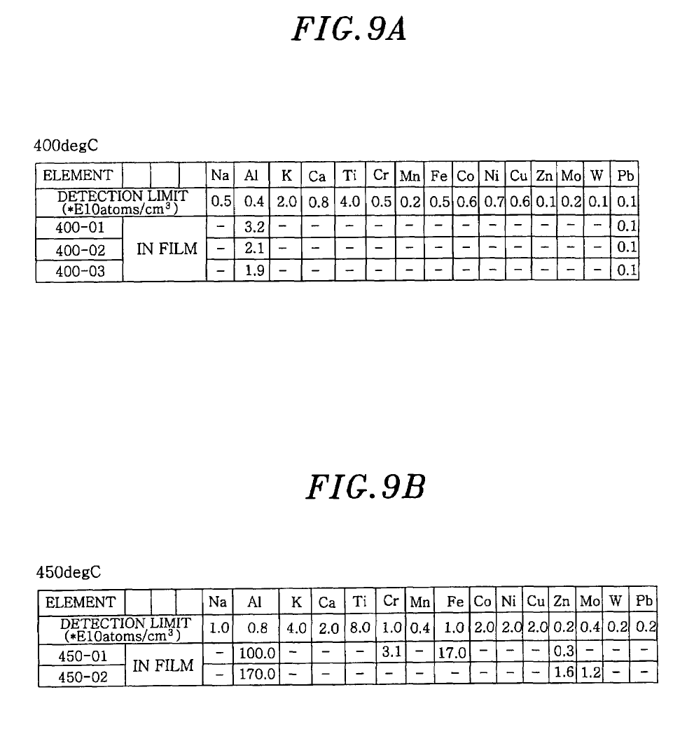

Next, there will be described results obtained by examining the relationship between the temperature of the substrate supporting table 104 during the coating film forming process and contaminations of a film formed during the film forming process after the coating film formation. FIGS. 9A and 9B show results of examining impurities in films formed on substrates after the coating film formation, in cases where the temperature of the substrate supporting table 104 during the coating film formation was set to be 400° C. and 450° C. Films formed on three substrates (wafers) when the temperature of the substrate supporting table 104 was 400° C. and two substrates (wafers) when the temperature of the substrate supporting table 104 was 450° C. were detected. In addition, in FIGS. 9A and 9B, the numbers in the leftmost column are wafer ID numbers. Further, detection results of respective elements are presented as a unit of 10¹⁰ atoms/cm³.

As shown in FIGS. 9A and 9B, a contamination amount of Al in the case where the temperature of the substrate supporting table 104 is 450° C. is larger than that in the case where the temperature of the substrate supporting table 104 is 400° C. Therefore, it is considered that the contamination is caused by diffusion of AlF due to increase in the temperature of the substrate supporting table 104, as mentioned above. Further, heavy metals such as Cr, Fe, and the like, were also detected. It is considered that heavy metals contained in the processing chamber 101 or the substrate supporting table 104 were precipitated. Therefore, in step 40, the temperature of the substrate supporting table 104 (the temperature of the substrate_supporting table 104 during the coating film formation) is preferably about 430° C. or less where a contamination amount of Al is 5×10¹⁰ atoms/cm³ or less that is acceptable, more preferably, about 400° C. or less such that contamination content can be more reduced.

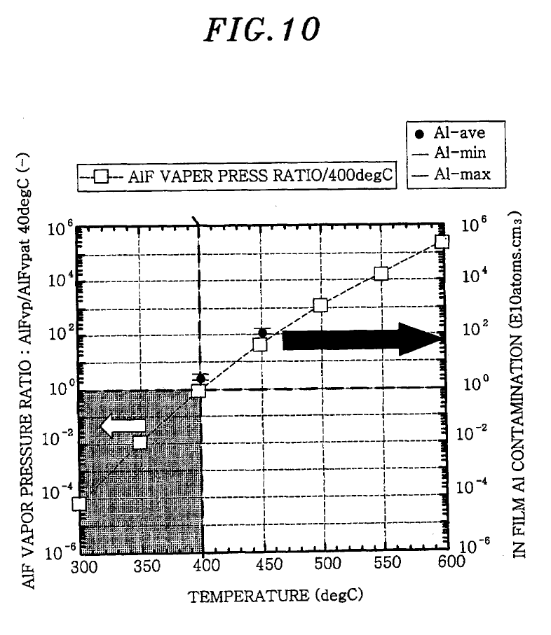

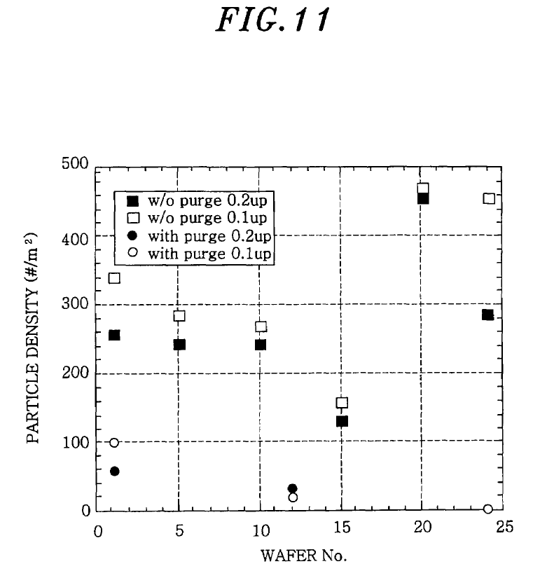

FIG. 10 is a graph showing the relationships between a temperature and a vapor pressure of AlF, and between the temperature of the substrate supporting table 104 during the coating film formation and a detection results of Al impurities in the film formed on the substrate after the coating film formation. In this case, the vapor pressure of AlF of a vertical axis in the graph is presented as a ratio of the vapor pressure of AlF on the assumption that the vapor pressure of AlF at 400° C. is 1. Further, the detection results of Al are presented as and I to respectively show the average value and a range of minimum and maximum values thereof.

Referring to FIG. 10, the vapor pressure of AlF in the case of 400° C. is about 1/100 of that in the case of 450° C., and a contamination amount of Al in the case of 400° C. is also about 1/100 of that in the case of 450° C. That is, the variation in the vapor pressure of AlF is related to the contamination amount of Al. Accordingly, it is found that the contamination amount of Al can be suppressed by maintaining the substrate supporting table 104 at a low temperature during the coating film formation.

Next, there will be described effects of reducing particles by purging the inside the processing chamber 101 in step 30 shown in FIGS. 2A to 2C. The purging of the inner space 101A shown in step 30 is a process for discharging particles or contaminations out of the inner space 101A by repeating supply of inert gas such as Ar and the like to the inner space 101A and discharge of the inert gas from the inner space 101A.

FIG. 11 shows particle densities (counts/m²) on the top surfaces of the substrate in a case where step 30 (purging) was performed and in a case where no purging was performed in the substrate processing method shown in FIG. 2A. In FIG. 11, ▪ represents the density of particles of 0.2 μm or more when no purging was performed, L represents the density of particles of 0.1 μm or more when no purging was performed, represents the density of particles of 0.2 μm or more when the purging was performed, and ◯ represents the density of particles of 0.1 μm or more when the purging was performed.

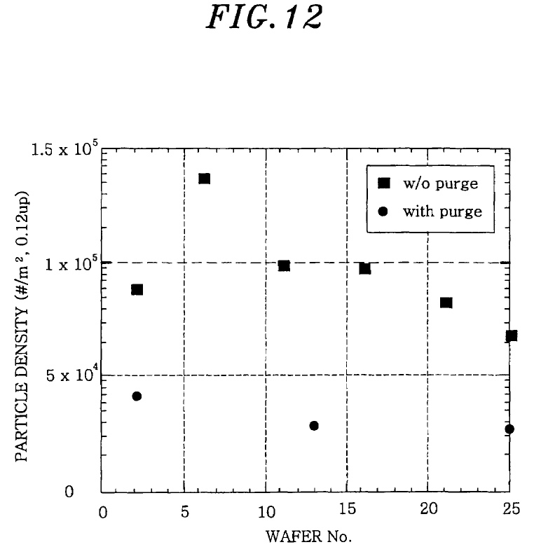

Further, FIG. 12 shows the particle densities (counts/m²) on the back side surface of the substrate in case where step 30 (purging) was performed and in case where no purging was performed in the substrate processing method of FIG. 2A. In FIG. 12, ▪ represents the density of particles of 0.12 μm or more when no purging was performed, and represents the density of particles of 0.12 μm or more when the purging was performed.

Referring to FIGS. 11 and 12, the density of particles was reduced in both the top and back side surfaces of the substrate when the purging was performed. Therefore, it is found that the amount of particles is reduced by performing the purging.

### Second Embodiment

Hereinafter, an example of a substrate processing method using the film forming apparatus 100 is described on the basis of the above-mentioned substrate processing method. The substrate processing was performed based on the substrate processing method shown in FIG. 2A in the following example.

First, the process in step 10 was performed as follows. The temperature of the substrate supporting table 104 was set to be 672° C., and a substrate (300 mm wafer) was loaded into the inner space 101A by using, e.g., a transfer robot or the like.

Next, W(CO)₆ maintained in the raw material supply unit 130C was sublimated to be a material gas and then supplied into the inner space 101A from the shower head 109 via the gas line 130, together with a carrier gas, e.g., Ar of which flow rate was 90 sccm and a diluent gas (purge gas), e.g., Ar of which flow rate was 700 sccm. In this case, the pressure in the inner space 101A was 20 Pa (0.15 Torr). As a result, the material gas was decomposed on the substrate, whereby a W film was formed on the substrate. The W film having a thickness of about 20 nm was formed for a time period of 150 seconds. This processing was performed on 250 substrates.

Next, the process in step 20 was performed as below. First, the temperature of the substrate supporting table 104 was decreased to be 400° C. Then, NF₃ and Ar were respectively supplied at flow rates of 230 sccm and 3000 sccm into the remote plasma generator 141, and a high frequency power of 2.7 kW was applied thereto for plasma-exciting, thereby creating active species including F radicals.

A cleaning gas (including a diluent gas) excited in the remote plasma generator 141 was supplied into the inner space 101A from the shower head 109 via the gas line 140. In this case, the pressure in the inner space 101A was 5320 Pa (39.9 Torr). The cleaning process was performed for 30 minutes.

Next, in order to check the cleaning, the processing chamber 101 was opened and the state of the processing chamber 101 was checked. As a result, it has been confirmed that the W film accumulated on the inner wall of the processing chamber 101, the shower head 109, the substrate supporting table 104, the supporting table cover 105, and the like, was removed, and there was no damage to those members.

Then, by returning to step 10 after performing step 30 and step 40, the substrate processing can be countinuously performed.

For example, in step 30, it is preferable to repeat supply of an inert gas such as Ar into the inner space 101A and discharge of the inert gas from the inner space 101A to perform, so-called “cycle purging”.

Further, step 40 is performed under the same condition as the film forming process of step 10, except for the temperature of the substrate supporting table 104. It is preferably to perform the coating film formation after the temperature of the substrate supporting table 104 is changed to, e.g., 400° C.

### Third Embodiment

Hereinafter, an example of a substrate processing based on the substrate processing method shown in FIG. 2B.

First, the process in step 10 was performed as follows. The temperature of the substrate supporting table 104 was set to be 600° C., and a substrate (300 mm wafer) was loaded into the inner space 101A by using, e.g., the transfer robot or the like.

Next, Ta(Nt-Am) (NMe₂)₃ maintained at 46° C. in the raw material supply unit was sublimated to be a material gas, and the material gas is supplied into the inner space 101A from the shower head 109 via the gas line 130, together with a carrier gas, e.g., Ar of which flow rate was 40 sccm. In this case, a diluent gas (purge gas), e.g., Ar, SiH₄, and NH₃ were also supplied into the inner space 101A from the shower head 109 via the gas line 120 at flow rates of 40 sccm, 500 sccm and 200 sccm, respectively.

In this case, the pressure in the inner pressure 101A was 40 Pa (0.3 Torr) . As a result, the material gas was decomposed on the substrate, whereby a TaSiN film was formed on the substrate. The film forming time was 150 seconds, and the thickness of the formed TaSiN was about 20 nm. The above process was performed on 250 substrates.

Next, the process in step 15 was performed as below. First, the temperature of the substrate supporting table 104 was decreased to be 250° C. Then, NF₃ and Ar were supplied into the remote plasma generator 141 at flow rates of 230 sccm and 3000 sccm, respectively, and a high frequency power of 1.2 kW was applied thereto for plasma-exciting, thereby creating active species including F radicals.

A cleaning gas (including a diluent gas) excited in the remote plasma generator 141 was supplied into the inner space 101A from the shower head 109 via the gas line 140. In this case, the pressure in the inner space 101A was set to be 133 Pa (1 Torr). The cleaning process was performed for 10 minutes.

Next, the process in step 20 was performed as follows. First, the temperature of the substrate supporting table 104 was increased to be 400° C. Then, NF₃ and Ar were supplied into the remote plasma generator 141 at flow rates of 230 sccm and 3000 sccm, respectively, and a high frequency power of 2.7 kW was applied thereto for plasma-exciting, thereby creating active species including F radicals.

A cleaning gas (including a diluent gas) excited in the remote plasma generator 141 was supplied into the inner space 101A from the shower head 109 via the gas line 140. In this case, the pressure in the inner space 101A was set to be 5320 Pa (39.9 Torr). The cleaning process was performed for 30 minutes.

Next, in step 30, there was performed the cycle purging where supply and stop of Ar used as a purge gas was repeated. That is, the cycle purging was performed by repeating maintenance of Ar, of which flow rate was 1000 sccm, at a pressure of 1 Torr (133 Pa), or maintenance of Ar, of which flow rate was 800 sccm, at a pressure of 0.5 Torr (66.5 Pa), for 20 seconds and discharge thereof for 10 seconds.

Next, step 40 was performed under the same condition as the film forming process of step 10, except for the temperature of the substrate supporting table 104. The coating film formation was performed after the temperature of the substrate supporting table 104 was changed to 400° C.

Thereafter, the processing was returned to step 10 and the film formation was performed, and it was found that particles and contaminations of Al in the film were reduced.

Further, in case the substrate processing method of FIG. 2C is performed, after performing the coating film formation at 400° C. in step 40, the temperature of the substrate supporting table 104 is preferably changed to, e.g., 600° C. similar to step 10 correspondingly to the treatment of step 45 and, then, the coating film formation is similarly performed. In this case, the quality of the coating film becomes fine, thereby improving adhesity of the coating film.

Further, while the above embodiments have been described to form the film including W or Ta on the substrate, the present invention is not limited thereto various film forming methods can be performed by using variety material gases such as a metal carbonyl gas and the like. In addition, although NF₃ has been exemplified as the cleaning gas, it is not limited thereto and various cleaning gases including F, e.g., fluorocarbon based gas and the like can be used.

### INDUSTRIAL APPLICABILITY

In accordance with the present invention, it is possible to provide a substrate processing method which is capable of efficiently maintaining an inner space of a processing chamber of a film forming apparatus in a clean state, thereby increasing productivity, and a storage medium for storing therein a program for executing the method on a computer.

This international application claims the benefit of Japanese Patent Application No. 2005-278367, filed on Sep. 26, 2005, the entire disclosure thereof being incorporated herein by reference.

What is claimed is:

1. A substrate processing method performed by a film forming apparatus including a substrate supporting table, for supporting a substrate to be processed, and having a heating unit therein, and a processing chamber in which the substrate supporting table is provided, the method comprising:
a film forming step for forming a film on the substrate by supplying a film forming gas into the processing chamber;
a cleaning step for cleaning the inside of the processing chamber by supplying a plasma-excited cleaning gas into the processing chamber after the film forming step; and
a coating step for forming a coating film in the processing chamber after the cleaning step,
wherein the cleaning step includes a high pressure cleaning where a pressure in the processing chamber is controlled such that the inside of the processing chamber is cleaned mainly by molecules formed by recombining radicals in the plasma-excited cleaning gas, and the coating step includes a low temperature film forming where the coating film is formed under the condition that the temperature of the substrate supporting table is set lower than that in the film formation on the substrate during the film forming step.

2. The method of claim 1, wherein the cleaning gas is formed of NF₃, and the film formed in the film forming step includes W.

3. The method of claim 2, wherein, in the high pressure cleaning, the pressure in the processing chamber is set to be 20 Torr or more.

4. The method of claim 3, wherein, in the high pressure cleaning, the temperature of the substrate supporting table is set to be 350° C. or more.

5. The method of claim 2, wherein the cleaning step includes a low pressure cleaning where the inside of the processing chamber is cleaned under the condition that the pressure in the processing chamber is set lower than that in the high pressure cleaning.

6. The method of claim 5, wherein, in the low pressure cleaning, the pressure in the processing chamber is set to be 10 Torr or less.

7. The method of claim 6, wherein, in the low pressure cleaning, the temperature of the substrate supporting table is set to be 300° C. or less.

8. The method of claim 5, wherein, in the low pressure cleaning, the temperature of the substrate supporting table is set lower than that in the high pressure cleaning.

9. The method of claim 5, wherein, in the cleaning step, the high pressure cleaning is performed after the low pressure cleaning.

10. The method of claim 1, wherein, in the low temperature film forming, the temperature of the substrate supporting table is set to be 430° C. or less.

11. The method of claim 1, wherein the coating step further includes a high temperature film forming where the coating film is formed in the processing chamber under the condition that the temperature of the substrate supporting table is set higher than that in the low temperature film forming.

12. The method of claim 11, wherein, in the coating step, the high temperature film forming is performed after the low temperature film forming.

13. The method of claim 1, further comprising a purge step for purging the processing chamber by using an inert gas, between the cleaning step and the coating step.

14. A storage medium storing a program executing a substrate processing method performed by a film forming apparatus on a computer, the apparatus including a substrate supporting table, for supporting a substrate to be processed, having a heating unit therein, and a processing chamber in which the substrate supporting table is provided, the method comprising:
a film forming step for forming a film on the substrate by supplying a film forming gas into the processing chamber;
a cleaning step for cleaning the inner space of the processing chamber by supplying a plasma-excited cleaning gas into the processing chamber after the film forming step; and
a coating step for forming a coating film in the processing chamber,
wherein the cleaning step includes a high pressure cleaning where a pressure in the processing chamber is controlled such that the inside of the processing chamber is cleaned mainly by molecules formed by recombining radicals in the plasma-excited cleaning gas, and the coating step includes a low temperature film forming where the coating film is formed under the condition that the temperature of the substrate supporting table is set lower than that in the film formation on the substrate during the film forming step.
